(19) United States
(12) Patent Application Publication
(10) Pub. No.: US 2005/0275025 A1
(43) Pub. Date: Dec. 15, 2005

(54) Semiconductor component and method for its production

(76) Inventor: Sven Lanzerstorfer, Feldkirchen (AT)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/132,486

(22) Filed: May 19, 2005

(30) Foreign Application Priority Data
May 19, 2004 (DE) 10 2004 024 885.0

(51) Int. Cl. H01L 27/01

(52) U.S. Cl. 257/350

(57) ABSTRACT

A semiconductor component having a vertical power transistor and at least one driver circuit for driving the vertical power transistor, and to a method for its production is disclosed. In the semiconductor component according to the invention, the layer thickness of the monocrystalline semiconductor layer in the region where the vertical power transistor is formed is less than the layer thickness of the monocrystalline semiconductor layer in the region where the driver circuit is formed. In particular, this may be achieved in that a surface region where the vertical power transistor is formed lies lower than a surface region where the driver circuit is formed. This makes it possible to reduce the on-state resistance of the semiconductor component without compromising its dielectric strength.

### CROSS-REFERENCE TO RELATED APPLICATIONS

This Utility Patent Application claims priority to German Patent Application No. DE 10 2004 024 885.0, filed on May 19, 2004, which is incorporated herein by reference.

### FIELD OF THE INVENTION

The present invention relates to a semiconductor component having a vertical power transistor and at least one driver circuit. The present invention furthermore relates to a method for producing such a semiconductor component.

### BACKGROUND

Power transistors are conventionally used for switching energy lines, for example in order to activate a motor, a magnet, a valve or a lamp. This means that they are used to switch voltages which are more than approximately 4 V and are usually 12 V, 14 V, 42 V or 48 V. The entire electricity supply in automobile technology, in particular for the safety relevant components, is for example carried out using such power transistors.

Power semiconductor components are also used in other fields in which dielectrically strong current switches are required.

Significant savings on costs as well as the assembly area can be achieved by integrating a power transistor and a driver circuit on a chip. The fail safety and the system reliability are also significantly improved.

When developing power semiconductor components, attempts are made in particular to optimize their breakdown strength while having a low on-state resistance and small space requirement.

A power transistor which is distinguished by very low values of a specific on-state resistance, which is defined as the product of the on-state resistance Ron and the chip area, is a DMOS transistor (DMOS=double diffused MOS).

FIG. 3 illustrates a representation of a vertical DMOS transistor of the prior art.

As illustrated by FIG. 3, an n-doped epitaxial layer 2 is applied on a heavily n-doped silicon substrate 1. In FIG. 3, section I denotes the DMOS region while section II denotes the logic region. A p-doped body region 5 is formed in the n-doped epitaxial layer 2. A source electrode 7 is arranged next to the p-doped body region 5. The source electrode 7 is connected to a source terminal structure 8. A p⁺-doped region 6 is provided for low-impedance connection of the source terminal structure 8 to the p-doped body region 5. A gate electrode 3 insulated by a gate oxide layer 4 is respectively arranged on both sides of the p-doped channel.

In the representation shown, the gate electrode is respectively arranged in a trench and extends vertically downward from the main surface of the DMOS region, i.e., in a direction perpendicular to the main surface of the DMOS region. The heavily doped semiconductor substrate 1 forms the drain electrode and is usually provided with a rear metallization 16. Usually, such power semiconductor components are adhesively bonded or soldered into packages via the rear metallization 16.

During the operation of such a DMOS transistor, the channel length is determined not by the length or depth of the gate electrode but by the extent of the p-doped body region along the gate electrode, i.e. in FIG. 3 from the lower edge of the body region 5 to the lower edge of the source electrode 7.

A particular feature of the DMOS transistor is its long and weakly doped drain path 25 or drift zone, i.e., in FIG. 3 the distance between the lower edge of the p-doped body region 5 and the upper edge of the n⁺-doped substrate, or the exodiffusion region of the substrate.

This drain path guarantees the high dielectric strength of the DMOS transistor, i.e., the high drain-source breakdown voltage. The dielectric strength depends on the one hand on the doping of the area and on the other hand on its length. The longer the drain path is, the higher the dielectric strength is; the weaker the doping of the drain path is, the higher its dielectric strength is.

For DMOS transistors, however, a low on-state resistance Ron is also sought. The on-state resistance Ron is likewise determined by the length of the drift zone in a vertical direction and its doping.

Depending on the design of the DMOS transistor, the trenches in which the gate electrode is placed may be formed as strips, grids or in the form of other polygons, in which case strip-shaped or honeycombed trench transistor cells are respectively obtained.

An increased dielectric strength with a lower on-state resistance Ron can be achieved in power transistors if a field plate or field electrode is inserted so that the drift path is electrostatically shielded against the gate electrode. No effect on the conductivity inside the drift path due to the gate electrode then takes place.

In particular, moreover, a compensation effect occurs since the field plate is usually held at a potential which is opposite to that of the doping of the drain path. For an equal blocking ability, the doping of the epitaxial layer 2 can therefore be increased.

The gate-drain capacitance is furthermore greatly reduced or, if the field electrode is connected to the source potential, converted into a less critical gate-source capacitance.

In the DMOS transistor illustrated in FIG. 3 with such a field plate, the latter may for example be arranged in the trench in which the gate electrode 3 is arranged, below the gate electrode and insulated from it and the surrounding epitaxial layer. In such an arrangement, the region of the gate electrode usually extends to the lower edge of the body region 5. Nevertheless, many alternative configurations of the field plate are implemented in DMOS transistors.

So-called smart power technologies comprise combinations of DMOS bipolar and CMOS or MOS technologies. For example, as illustrated in FIG. 3, the driver circuit belonging to a power transistor may be implemented in a CMOS technology. The driver circuits belonging to the logic are arranged in the logic region II in FIG. 3.

In FIG. 3, a p-doped well 10 is formed in the n-doped epitaxial layer 2. The first and second source/drain regions 11 and 12, for example belonging to an MOS transistor, are formed in this well and connected out via respective terminal structures 13. A gate electrode 15 is insulated by a gate oxide 14 from the conductive channel which is formed between the first and second source/drain regions.

Since the circuits of the logic in this smart power technology are not designed as power semiconductor components, it is necessary to shield them against the drain electrode 1. For this reason, a p-doped well is usually produced in the epitaxial layer 10 by diffusion from the surface downward, i.e., toward the redoped region 1, and the depth of the diffused well is adjusted so that the required dielectric strength is obtained. The profile may also be retrograde, i.e., homogeneous as far as a particular depth, there being a peak value of the doping in the lower region which is achieved, for example, by suitable adjustment of the parameters during the ion implantation.

In order to achieve a particular dielectric strength of the driver circuits, the p-doped well 10 must have a certain minimum thickness, so in turn there is also a requisite minimum thickness of the epitaxial layer 2. Since the logic regions and the DMOS transistors are formed on a surface of the epitaxial layer 2, the problem therefore arises that the DMOS transistor has too high an on-state resistance Ron.

Because the breakdown strength of the DMOS transistor is usually increased owing to the field electrode, the epitaxial layer for the DMOS transistor could be thinner or have heavier doping, so that the on-state resistance Ron would in turn be less. In other words, the layer thickness of the epitaxial layer 2 in the arrangement shown in FIG. 3 is optimized not for the DMOS transistor but for the logic region.

### SUMMARY

Embodiments of the present invention provide a semiconductor component and method for producing the semiconductor component. In one embodiment, the invention provides a semiconductor component including a monocrystalline semiconductor layer having a transistor region and a logic region. A vertical power transistor is at least partially formed in the transistor region. At least one driver circuit at least partially formed in the logic region, wherein the monocrystalline semiconductor layer has a first layer thickness in the transistor region and a second layer thickness in the logic region, wherein the first layer thickness is less than the second layer thickness.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A illustrates a first embodiment of the semiconductor component according to the invention.

FIG. 1B illustrates a second embodiment of the semiconductor component according to the invention.

FIG. 2 illustrates a third embodiment of the semiconductor component according to the invention.

FIG. 3 illustrates a representation of a conventional component.

FIGS. 4A-4C illustrate a production method for producing the semiconductor component according to the invention.

FIGS. 5A-5C illustrate an alternative method for producing the semiconductor component according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one embodiment, the present invention provides a semiconductor component having a vertical power transistor and at least one driver circuit, in which the on-state resistance Ron of the power transistor can be reduced while maintaining the same dielectric strength of the driver circuit.

The present invention, includes a semiconductor component including a vertical power transistor and at least one driver circuit, which is suitable for driving the vertical power transistor, both of which are at least partially formed in a monocrystalline semiconductor layer, which comprises a surface and a lower side located on the opposite side of the semiconductor layer from the surface, and which is arranged on a substrate layer, the vertical power transistor having a first zone of a first conductivity type, a first region of a second conductivity type, embedded in the first zone, and a second region of the first conductivity type, next to the first region, the second region being spatially separated from the first zone by the first region and the second region being connected to a source terminal structure and forming a source electrode, the first zone, the first region and the second region being formed in the monocrystalline semiconductor layer, a drain electrode, which is connected to the first zone and is formed in the substrate layer, a gate electrode, which is suitable for controlling the conductivity in the channel formed in the first region between the second region and the first zone by the field effect, a distance between a first main surface of the monocrystalline semiconductor layer, in which the first zone, the first region and the second region of the vertical power transistor are formed, and the lower side of the monocrystalline semiconductor layer being less than a distance between a second main surface of the monocrystalline semiconductor layer, in which the driver circuit is formed, and the lower side of the monocrystalline semiconductor layer.

The layer thickness of the monocrystalline semiconductor layer in the region where the vertical power transistor is formed is less than the layer thickness of the monocrystalline semiconductor layer in the region where the driver circuit is formed.

The resistance contribution of the epitaxial layer, which is usually in the range of approximately 80% of the total resistance in smart products, is therefore reduced without lowering the dielectric strength of the semiconductor component to below the requirements. The chip area of the semiconductor component can consequently be reduced. Another advantage of the different layer thicknesses for the DMOS region and the logic region, when simultaneously using the source and body implementations as in the logic, is that the DMOS breakdown voltage can be set lower than that of the p-well of the logic (especially in the case of field plate trench transistors), so that the robustness of the chip can be increased.

The particular advantage is obtained that the DMOS region breaks down if an overvoltage or voltage peak occurs, rather than the p-wells of the logic. This is advantageous since the currents then occurring can be dissipated better via the DMOS region than via the logic metallization.

Preferably, the driver circuit is at least partially formed in a region of a second conductivity type arranged in the monocrystalline semiconductor layer. This region of the second conductivity type is usually provided in order to shield the driver circuit electrostatically against the drain contact on the rear side.

Preferably, the rear side of the semiconductor body is planar and the first main surface and the second main surface are mutually offset in a vertical direction. This means that the surfaces are respectively not coplanar but offset parallel to each other.

According to one embodiment of the present invention, therefore, the DMOS region is placed lower than the logic region, so that the respective surfaces are not coplanar but are offset parallel to each other. The transition region between the original silicon surface, i.e., the surface for the logic region, and the lower surface can then be configured in any desired way.

The advantage of placing the DMOS part further down is that the layer thickness of the epitaxial layer is reduced precisely in the weakly doped region of the epitaxial layer (i.e., far away from the rear side of the semiconductor body) where exodiffusion of the heavily doped semiconductor region substrate usually takes place. Furthermore, part of the topology of the DMOS region can be relaxed because these areas are likewise lower.

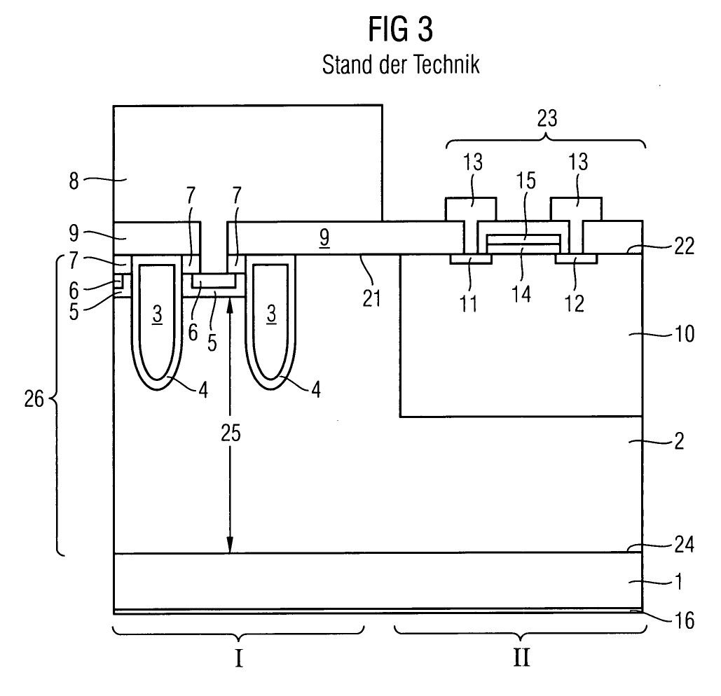

More specifically, the advantage is obtained that the lower placement of the DMOS regions allows previously protruding parts or regions with a high topology, for example the source terminal structure denoted by the reference 8 in FIG. 3, can be moved down so that the surface of the entire component is planarized and the further processing is significantly facilitated.

Preferably, the difference between the distance between the second main surface of the monocrystalline semiconductor layer and the lower side, and the distance between the first main surface of the monocrystalline semiconductor layer and the lower side is greater than or equal to 0.2 μm. Specifically, the outlay associated with the production of such a semiconductor component for smaller differences is not worthwhile since this only slightly reduces the on-state resistance Ron.

Preferably, the difference between the distance between the second main surface of the monocrystalline semiconductor layer and the lower side, and the distance between the first main surface of the monocrystalline semiconductor layer and the lower side is less than or equal to 2 μm. A larger difference is difficult to cope with in process technology since, for example, such height differences lead to exposure problems in subsequent lithography steps.

The present invention can be implemented with various types of vertical power transistors and driver circuits.

The term “driver circuit” here covers any types of circuits which are suitable for driving the power transistor, for example transistors, e.g. bipolar transistors, MOS transistors in CMOS technology, low-voltage CMOS technology, planar CMOS structures, high-voltage n-p channel transistors/diodes or even passive components, for example resistors.

The present invention can likewise be carried out with any of the configurations customarily used for vertical power transistors.

For example, the power transistor may be designed as a trench transistor in which the gate electrode is arranged in a trench formed in the monocrystalline semiconductor layer. The power transistor may also be a planar transistor, in which the gate electrode is formed on the first surface region of the monocrystalline semiconductor layer.

The power transistor may furthermore comprise at least one field plate, which is arranged in a trench formed in the region of the first surface region in the monocrystalline semiconductor layer. The trench is usually etched to a depth such that the field plate extends into the drift zone.

In particular, the gate electrode and the field plate may be arranged in the same trench, the field plate being arranged in a lower trench region and the gate electrode being arranged in an upper trench region. In this case, the field plate and the gate electrode may be electrically insulated from each other so that the field plate can be placed at a potential independent of the gate voltage. It is also possible for the trench to extend to a certain depth inside the drift zone and for the gate electrode to act as a field plate in the lower trench region, i.e., a separate field plate is not provided. In this case, the insulator layer for insulating the gate electrode or field plate from the drift zone is designed to be thicker in the lower trench region than in the upper trench region.

The present invention also relates to a method for producing such a semiconductor component, including providing a substrate layer with a semiconductor layer arranged on it, the semiconductor layer having a surface and a lower side, defining a first main surface for the vertical power transistor, defining a second main surface for the driver circuit, the distance between the first main surface and the lower side being less than the distance between the second main surface and the lower side, fabricating the vertical power transistor and the driver circuit.

Defining the first surface region may, in particular, include selective thermal oxidation of the first surface region, this being carried out so that monocrystalline semiconductor material is consumed, and subsequently removal of the thermal oxide layer in the first surface region. The method according to the invention can thereby be carried out in a particularly straightforward way, and integrated into the rest of the production method of the semiconductor component since a thermal oxidation step is usually provided in order to produce the field oxide which insulates the active regions of the driver logic from one another.

Nevertheless, defining the first surface region may alternatively comprise selective etching of monocrystalline semiconductor material in the first surface region. This offers the advantage that the etching depth is not dependent on the layer thickness of the field oxide produced during the thermal oxidation method. In particular, the DMOS region can be lowered by any desired values.

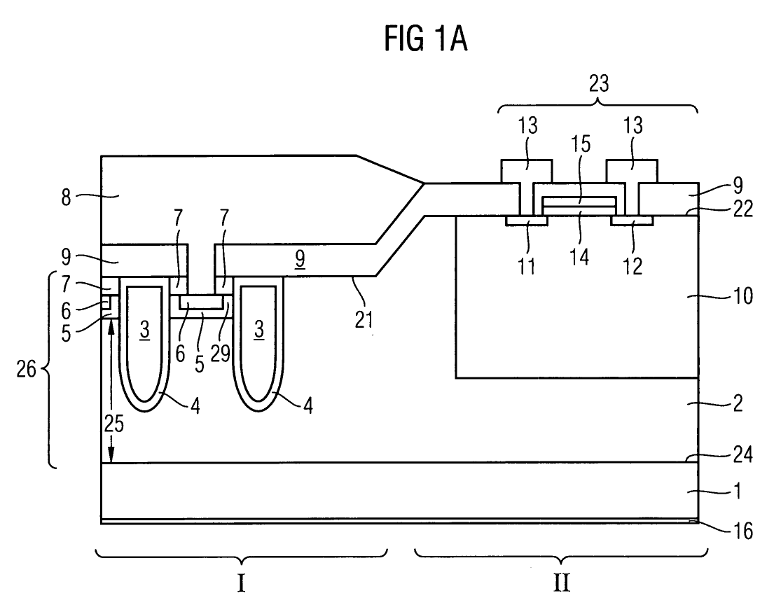

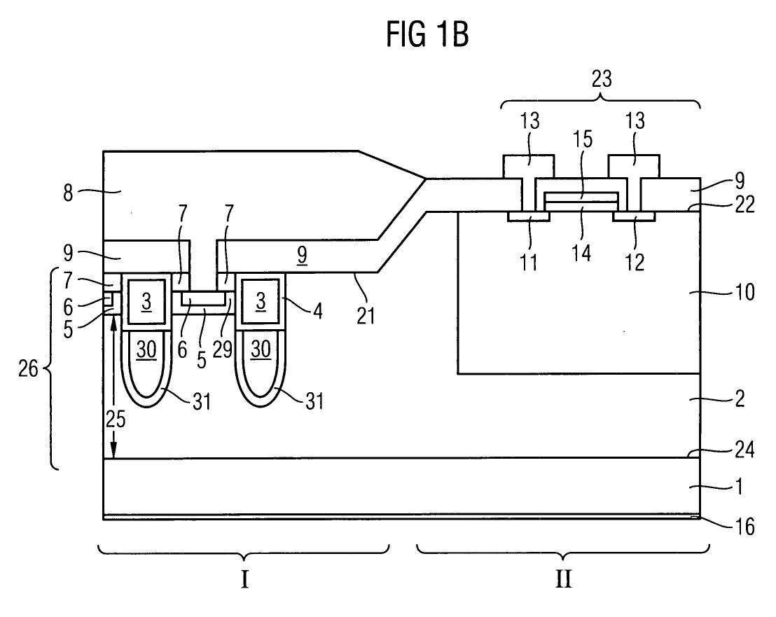

FIG. 1A illustrates a first embodiment of the present invention, which contains basically the same component parts as the component represented in FIG. 3 and in which the gate electrode for the DMOS transistor is arranged in a trench.

The DMOS region is denoted by I in the left-hand part of FIG. 1A, while II denotes the logic region.

In FIG. 1A, the same references denote the same component parts as in FIG. 3. In FIG. 1A, a p-doped body region 5 is created by diffusion in the epitaxially formed layer 2, respectively between two gate electrodes 3 which are each arranged in a trench and are insulated from the epitaxial layer 2 by a gate oxide layer 4. Within this region 5, p⁺-doped regions 6 are respectively formed likewise by diffusion. The source electrodes 7 are respectively formed above the p⁺-doped body regions. The source electrodes are respectively connected to a source terminal structure 8, which is usually metallic and may, for example, be made of aluminum. The connection of the terminal structure 8 to the source electrodes 7 may be carried out differently than as represented in FIG. 1A. An insulator layer 9 is arranged on the surface 21 of the epitaxial layer 2.

During the operation of this DMOS transistor a conductive channel 29, whose conductivity is controlled by the gate electrode 3, is formed inside the body region 5 between the source electrode 7 and the section of the epitaxial layer 2 lying directly below the body region 5. The drift path 25 is arranged between the section of the epitaxial layer 2 lying directly below the body region 5 and the drain electrode 27.

In the right-hand part of FIG. 1A, the corresponding logic circuits are formed at least partially in a p-doped well 10.

As illustrated in FIG. 1A, the effective thickness of the epitaxial layer 2 inside the DMOS region is less than the thickness of the epitaxial layer inside the logic region II. In other words, the distance of the main surface of the epitaxial layer 2 from the lower side of the epitaxial layer is less in the region I than in the region II. This means that the horizontal plane which joins together the topmost monocrystalline regions in the region I lies lower than the horizontal plane which joins together the topmost monocrystalline regions in the area II. In this context, the expressions “high” and “low” refer to the distance from the substrate lower side, or a horizontal plane which adjoins the substrate at the bottom, in a vertical direction.

As also illustrated in FIG. 1A, the transition from the metallization layer 8, which is connected to the source electrodes 7, to the logic region II is no longer vertical but oblique.

FIG. 1B illustrates a second embodiment of the present invention, in which the gate electrode for the DMOS transistor is arranged in a trench and a field plate is furthermore provided.

The DMOS region is denoted by I in the left-hand part of FIG. 1B, while II denotes the logic region.

In FIG. 1B, the same references denote the same component parts as in FIG. 3. In FIG. 1B, a p-doped body region 5 is created by diffusion in the epitaxially formed layer 2, respectively between two gate electrodes 3 which are each arranged in a trench and are insulated from the epitaxial layer 2 by a gate oxide layer 4. Within this region 5, p⁺-doped regions 6 are respectively formed likewise by diffusion. The source electrodes 7 are respectively formed above the p⁺-doped body regions. The source electrodes are respectively connected to a source terminal structure 8, which is usually metallic and may, for example, be made of aluminum. The connection of the terminal structure 8 to the source electrodes 7 may be carried out differently than as represented in FIG. 1B. An insulator layer 9 is arranged on the surface 21 of the epitaxial layer 2.

Below the gate electrode, inside the trench, a field plate 30 is respectively arranged and is electrically insulated from the gate electrode. The field plate is surrounded by an insulator layer 31, for example of silicon dioxide. This insulator layer 31 is usually thicker than the gate oxide layer 4.

The invention may of course also be applied to vertical power transistors without a field plate, or with an alternative arrangement of the field plate. For example, the lower part of the gate oxide layer 4, which insulates the gate electrode 3 from the field plate 30, may even be omitted so that there is only an electrode which is surrounded by a thicker insulator layer in a lower trench region than in an upper trench region.

During the operation of this DMOS transistor a conductive channel 29, whose conductivity is controlled by the gate electrode 3, is formed inside the body region 5 between the source electrode 7 and the section of the epitaxial layer 2 lying directly below the body region 5. The drift path 25 is arranged between the section of the epitaxial layer 2 lying directly below the body region 5 and the drain electrode 27. The field plate 30 is connected to the source potential.

In the right-hand part of FIG. 1B, the corresponding logic circuits 23 are formed at least partially in a p-doped well 10.

As illustrated in FIG. 1B, the effective thickness of the epitaxial layer 2 inside the DMOS region is less than the thickness of the epitaxial layer inside the logic region II. In other words, the distance of the main surface of the epitaxial layer 2 from the lower side of the epitaxial layer is less in the region I than in the region II. This means that the horizontal plane which joins together the topmost monocrystalline regions in the region I lies lower than the horizontal plane which joins together the topmost monocrystalline regions in the area II. In this context, the expressions “high” and “low” refer to the distance from the substrate lower side, or a horizontal plane which adjoins the substrate at the bottom, in a vertical direction.

As also illustrated in FIG. 1B, the transition from the metallization layer 8, which is connected to the source electrodes 7, to the logic region II is no longer vertical but oblique.

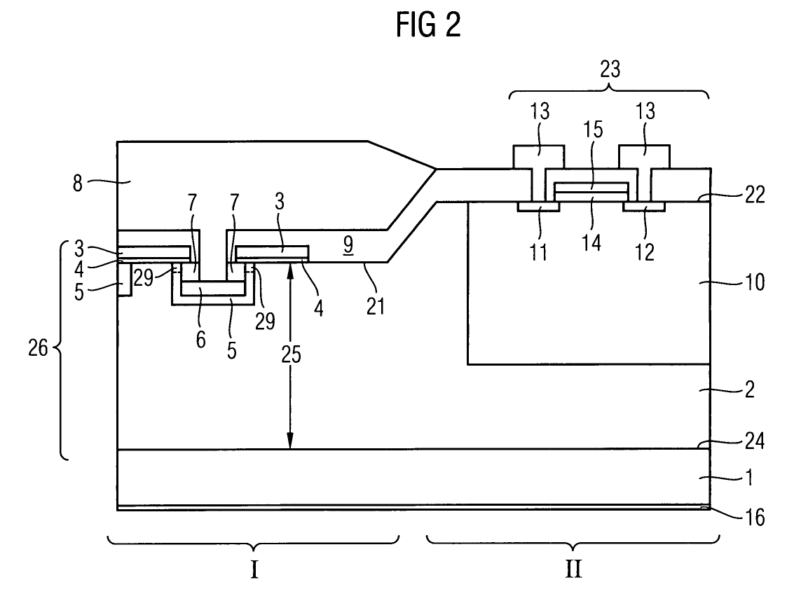

FIG. 2 illustrates a third embodiment of the present invention in which, unlike in FIGS. 1 and 3, the gate electrodes 3 are formed not in trenches but on the surface of the epitaxial layer 2.

The logic region II represented in FIG. 2 corresponds to that of FIGS. 1 and 3. In the left-hand part of FIG. 2, the p-doped body region 5 is formed in the n-doped epitaxial layer 2 and insulated from the source terminal structure 8 lying above by the p⁺-doped region 6. Source electrodes, with which contact is made via the source terminal structure 8, are arranged on the surface of the n-doped epitaxial layer 2. Here as well, of course, the connection between the source terminal structure 8 and the source electrode 7 may be carried out in any desired way. A field plate may furthermore be arranged at a suitable position.

A conductive channel 29, whose conductivity is controlled by the gate electrode 3, is formed between the source electrode 7 and the part of the n-doped region 2 next to the body region 5, inside the body region 5 and below the gate electrode 3. Here again, moreover, the current flows in a vertical direction, i.e. firstly in a substantially horizontal direction from the source electrode 7 via the aforementioned conductive channel 29 into the part of the epitaxial layer 2 laterally next to the body region 5, and from there via the drift path 25 to the drain electrode 1.

An insulator material 9 is applied above the epitaxial layer 2.

Similarly as in FIGS. 1A and 1B, the main surface in which the DMOS transistor is formed is arranged lower than the main surface in which the logic circuit is arranged. In other words, the thickness of the epitaxial layer 2 in the region of the DMOS transistor is thinner than the thickness of the epitaxial layer 2 in the region of the logic, the lower side of the epitaxial layer being substantially planar and the surface 21 for the DMOS region and the surface 22 for the logic region being offset parallel to each other.

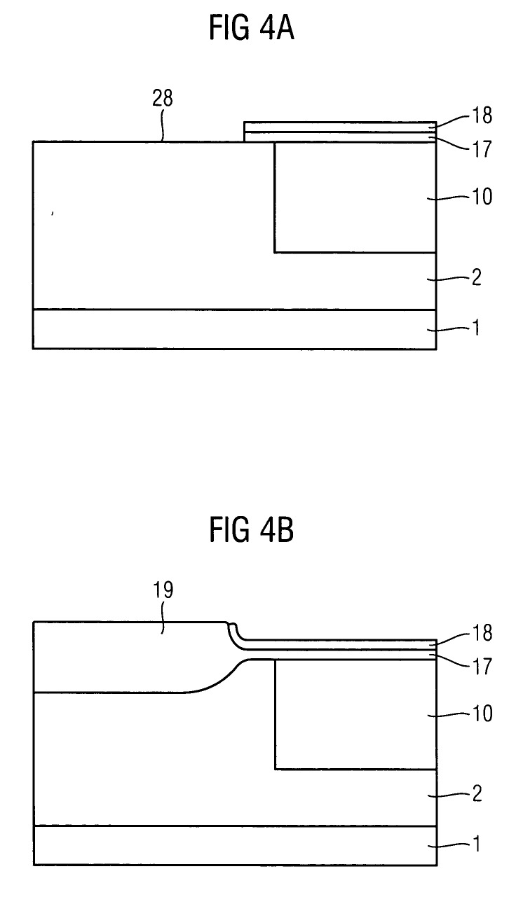

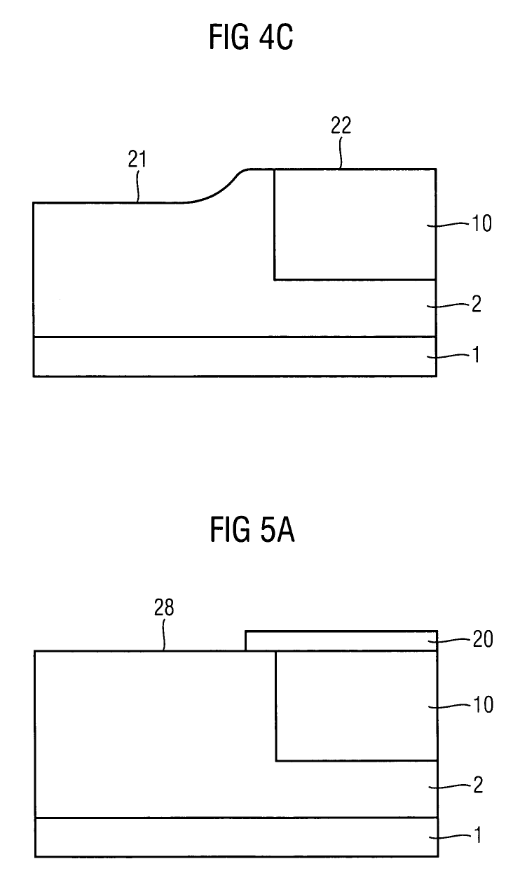

FIGS. 4A to 4C illustrate one embodiment of the production of the semiconductor component according to the invention. It should be remembered here that this is only a schematic representation of the method by which lower placement of the surface 21 for the DMOS region is achieved. The other methods correspond to those which are customarily used for the production of a DMOS transistor and the associated logic.

In FIG. 4A, reference 1 denotes an n⁺-doped silicon substrate on which an n-doped epitaxial layer 2 is applied. The thickness of the epitaxial layer 2 is dimensioned so as to be 4 μm after fabrication of the DMOS transistor which, for example, is in this case produced for a voltage class of 60 V. Since diffusion of the substrate 1 out takes place during the production of the DMOS transistor, the layer thickness of the epitaxial layer must correspondingly be selected to be more than 4 μm. It is nevertheless clear that other layer thicknesses of the epitaxial layer 2 may also be selected, depending on the voltage class for which the DMOS transistor is rated.

In order to define the logic region II, a p-doped well 10 is formed in the right-hand part of the substrate, for example by ion implantation. In the standard process for producing CMOS component parts, the formation of the wells is followed by definition of the active areas, during which a field oxide that insulates neighboring active areas from one another is applied, for example by LOCOS technology. Since the future active areas are shown in the representations given, no deposition of a field oxide therefore takes place in the cross-sectional view of the logic region II as shown, and the active regions are covered with a cover layer, which for example comprises an SiO₂ layer 17 and an Si₃N₄ layer 18.

As illustrated in FIG. 4B, thermal oxidation is carried out in a subsequent operation so that a thick silicon dioxide layer 13 is formed above the epitaxial layer 2 in the left-hand part of the representation, and no oxide growth takes place below the regions covered by the silicon dioxide layer 17 and the silicon nitride layer 18. An exemplary layer thickness is e.g., 1 μm.

As illustrated in FIG. 4C, after the logic region II has been covered with a suitable cover material, the LOCOS layer is removed in a subsequent step, for example by wet chemical etching with DHF (dilute hydrofluoric acid). With a typical LOCOS thickness of 1 μm, for example, the DMOS region may be placed approximately 0.5 μm lower. FIG. 4C thus illustrates an epitaxial layer 2, which has two surface regions 21 and 22 and is applied on a semiconductor substrate 1. The DMOS transistor is subsequently defined on the surface region 21, while the driver circuits of the logic are defined on the surface region 22. The surface region 21 is offset relative to the surface region 22 in a direction perpendicular to the substrate surface, so that the part of the epitaxial layer lying below the surface region 21 is thinner than the part of the epitaxial layer 2 below the surface region 22.

In subsequent method operations, the DMOS transistor and the component parts of the logic region are fabricated according to known methods so that, for example, the component represented in FIG. 1 or 2 is obtained.

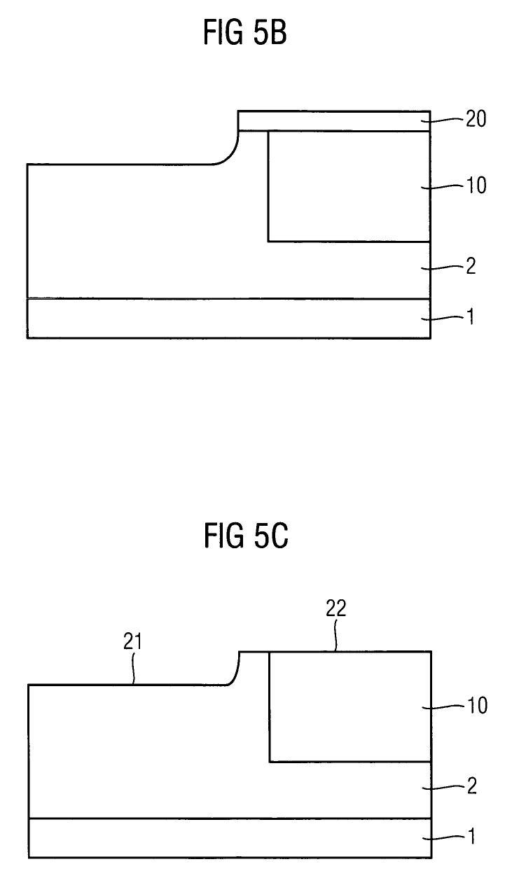

FIGS. 5A to 5C illustrate an alternative method for producing the component according to the invention. The starting point is again the heavily n⁺-doped silicon substrate with the epitaxial layer 2 applied on it and the p-well region 10 defined therein for the logic region II. Next, the logic region II is covered with a suitably selected cover layer 20, which is applied in a suitable layer thickness. After that, the uncovered surface of the epitaxial layer 2 is etched by a suitable etching method.

The etching may be carried out by known methods, for example by wet chemical, isotropic or anisotropic plasma etching or by reactive ion etching. Compared with those described above, this production method offers the advantage that the etching depth can be set independently of the field oxide thickness inside the logic region. Here, the etching time is dimensioned such that the surface region 21 for the DMOS region is etched 1 μm deep so that, in the finished component, the DMOS region is lowered by 1 μm downward relative to the logic region. After the end of the etching method, the cover layer 20 is removed. The illustrated in FIG. 5C is obtained.

As illustrated in FIG. 5C, the surface for the DMOS region 21 lies lower than the surface for the logic region 22. In other words, the layer thickness of the epitaxial layer 2 in the DMOS region has been reduced compared with the layer thickness of the epitaxial layer in the logic region.

For the usual structure sizes of power ICs, placing the DMOS region approximately 1 μm lower still causes no disadvantages during the exposure. Placing the DMOS surface 1 μm lower can reduce the contribution of the epitaxial layer to the Ron value by 25%, since the drift path in the epitaxial layer 2 now amounts to 3 μm instead of 4 μm, while still having a sufficient dielectric strength. This leads to a reduction in the total value of Ron by 20%. As a consequence, the chip area can in turn be reduced by 14% overall, assuming that the DMOS region I occupies 70% and the logic region II 30% of the total area.

The further processing of the structure illustrated in FIG. 5C is carried out according to known methods, by which the DMOS transistor and the driver circuits of the logic region are fabricated.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor component comprising:
a monocrystalline semiconductor layer having a transistor region and a logic region;
a vertical power transistor at least partially formed in the transistor region; and
at least one driver circuit at least partially formed in the logic region, wherein the monocrystalline semiconductor layer has a first layer thickness in the transistor region and a second layer thickness in the logic region, wherein the first layer thickness is less than the second layer thickness.

2. The semiconductor component of claim 1, wherein the monocrystalline semiconductor layer is defined by a main surface and a lower side, and where the first layer thickness is defined between the main surface and the lower side in the transistor region, and the second layer thickness is defined between the main surface and the lower side in the transistor region.

3. The semiconductor component of claim 2, further comprising:
a drain electrode positioned adjacent the lower side, along the transistor region and the logic region.

4. The semiconductor component of claim 1, further comprising:
a gate electrode; and
a drain electrode.

5. The semiconductor component of claim 1, wherein the monocrystalline semiconductor layer is an epitaxial layer.

6. The semiconductor component of claim 5, wherein the epitaxial layer is n-doped.

7. The semiconductor component of claim 1, further comprising:
a p-doped well formed in the logic region of the monocrystalline layer.

8. A semiconductor component comprising:
a vertical power transistor; and
a monocrystalline layer which comprises a surface and a lower side located on the opposite side of the semiconductor layer from the surface, and which is arranged on a substrate layer, the vertical power transistor having a first zone of a first conductivity type, a first region of a second conductivity type, embedded in the first zone;
at least one driver circuit, configured for driving the vertical power transistor, at least partially formed in the monocrystalline semiconductor layer;
a second region of the first conductivity type, next to the first region, the second region being spatially separated from the first zone by the first region and the second region being connected to a source terminal structure and forming a source electrode, the first zone, the first region and the second region being formed in the monocrystalline semiconductor layer;
a drain electrode, which is connected to the first zone and is formed in the substrate layer;
a gate electrode, which is suitable for controlling the conductivity in the channel formed in the first region between the second region and the first zone by the field effect; and
a distance between a first main surface of the monocrystalline semiconductor layer, in which the first zone, the first region and the second region of the vertical power transistor are formed, and the lower side of the monocrystalline semiconductor layer being less than a distance between a second main surface of the monocrystalline semiconductor layer, in which the driver circuit is formed, and the lower side of the monocrystalline semiconductor layer.

9. The semiconductor component of claim 8, wherein the driver circuit is at least partially formed in a region of a second conductivity type arranged in the monocrystalline semiconductor layer.

10. The semiconductor component of claim 8, wherein the first main surface and the second main surface are offset parallel to each other in a vertical direction.

11. The semiconductor component of claim 8, wherein the difference between the distance between the second main surface of the monocrystalline semiconductor layer and the lower side, and the distance between the first main surface of the monocrystalline semiconductor layer and the lower side is greater than or equal to 0.2 μm.

12. The semiconductor component of claim 8, wherein a difference between the distance between the second main surface of the monocrystalline semiconductor layer and the lower side, and the distance between the first main surface of the monocrystalline semiconductor layer and the lower side is less than or equal to 2 μm.

13. The semiconductor component of claim 8, which has at least one field plate, which is arranged in a trench formed in the region of the first main surface in the monocrystalline semiconductor layer.

14. The semiconductor component of claim 13, wherein the gate electrode is arranged in the trench.

15. The semiconductor component of claim 8, wherein the gate electrode is arranged in a trench formed in the region of the first main surface in the monocrystalline semiconductor layer.

16. A method for producing a semiconductor component, which comprises a vertical power transistor and at least one driver circuit suitable for driving the vertical power transistor, having the steps of:
providing a substrate layer with a semiconductor layer arranged on it, the semiconductor layer having a surface and a lower side;
defining a first main surface for the vertical power transistor;
defining a second main surface for the driver circuit; forming the vertical power transistor, this step comprising:
providing a first zone of a first conductivity type;
providing a first region of a second conductivity type, embedded in the first zone; and
providing a second region of the first conductivity type, next to the first region, the second region being spatially separated from the first zone by the first region and the second region being connected to a source terminal structure and forming a source electrode, the first zone, the first region and the second region being formed in the monocrystalline semiconductor layer;
providing a drain electrode, which is connected to the first zone and is formed in the substrate layer;
providing a gate electrode, which is suitable for controlling the conductivity in the channel formed in the first region between the second region and the first zone by the field effect; and
fabricating the driver circuit;
the distance between the first main surface and the lower side being less than the distance between the second main surface and the lower side.

17. The method as claimed in claim 16, wherein the first and second main surfaces are designed so that they are mutually offset in a direction perpendicular to the surface direction.

18. The method as claimed in claim 17, wherein the step of defining the first main surface comprises selective thermal oxidation of a part of the surface of the semiconductor layer, this step being carried out so that monocrystalline semiconductor material is consumed, and removal of the thermal oxide layer from the part of the surface when the first main surface is to be defined.

19. The method as claimed in claim 17, wherein the step of defining the first main surface comprises etching of monocrystalline semiconductor material in the region of the first main surface, while the second main surface is covered with a cover layer.

20. A semiconductor component comprising:
a monocrystalline semiconductor layer having a transistor region and a logic region;
a vertical power transistor at least partially formed in the transistor region; and
at least one driver circuit at least partially formed in the logic region, wherein the monocrystalline semiconductor layer has a first layer thickness in the transistor region and a second layer thickness in the logic region, wherein the first layer thickness is less than the second layer thickness.

21. A semiconductor component comprising:
a monocrystalline semiconductor layer having a transistor region and a logic region;
a vertical power transistor at least partially formed in the transistor region; and
at least one driver circuit at least partially formed in the logic region, wherein the monocrystalline semiconductor layer has a first layer thickness in the transistor region and a second layer thickness in the logic region, wherein the first layer thickness is less than the second layer thickness.
